(19) United States
(12) Patent Application Publication
(10) Pub. No.: US 2018/0054076 A1
(43) Pub. Date: Feb. 22, 2018

(54) MAINS-OPERABLE BATTERY CHARGING DEVICE AND CHARGING SYSTEM

(71) Applicant: Hilti Aktiengesellschaft, Schaan (LI)

(72) Inventor: Michael Wagner, Aitrang (DE)

(21) Appl. No.: 15/556,589

(22) PCT Filed: Mar. 10, 2016
(86) PCT No.: PCT/EP2016/055110

§ 371 Date: Sep. 7, 2017

(30) Foreign Application Priority Data
Mar. 10, 2015 (EP) 15158344.0

(51) Int. Cl. H02J 7/00; H05K 7/20

(52) U.S. Cl. CPC H02J 7/0055; H05K 7/20145; H02J 7/0045; H02J 7/0013

(57) ABSTRACT

A mains-operable battery charging device (100) including a charger housing (90) which includes a main charging interface (80) designed for exchangeably accommodating a main rechargeable tool battery (10) of a hand-held power tool, and including a charging electronics system (70) which is situated within the charger housing (90) and is designed for charging a main rechargeable tool battery (10) accommodated in the main charging interface (80) with a main charging voltage (U10), characterized in that the battery charging device (100) includes at least one auxiliary charging interface (21, 31) via which an auxiliary rechargeable tool battery (20, 30) is connectable to the battery charging device (100) and is chargeable with an auxiliary charging voltage (U20, U30) which differs from the main charging voltage (U10).

The present invention relates to a mains-operable battery charging device including a charger housing which includes a main charging interface designed for exchangeably accommodating a main rechargeable tool battery of a hand-held power tool, for example a hammer drill or a combi-hammer. The battery charging device further includes a charging electronics system which is situated within the charger housing and is designed for charging a main rechargeable tool battery accommodated in the main charging interface with a main charging voltage. The present invention also relates to a charging system including a mains-operable battery charging device and a main rechargeable tool battery.

### SUMMARY OF THE INVENTION

It is an object of the present invention to provide a mains-operable battery charging device and a charging system which are usable in diverse ways. With respect to the battery charging device, the object is achieved in that the battery charging device includes at least one auxiliary charging interface via which an auxiliary rechargeable tool battery is connectable to the battery charging device and is chargeable with an auxiliary charging voltage which differs from the main charging voltage.

The main rechargeable tool battery and the auxiliary rechargeable tool battery may be of different types, in particular the main rechargeable tool battery and the auxiliary rechargeable tool battery may be designed and/or intended for operating different types of hand-held power tools.

The present invention incorporates the finding that main rechargeable tool batteries and auxiliary rechargeable tool batteries previously could not be charged using one and the same battery charging device, in particular when they are of different types. In this way, it is not possible, for example, with the aid of battery charging devices from the prior art, to charge an auxiliary rechargeable tool battery with a nominal voltage of 14 volts or 22 volts while simultaneously charging a main rechargeable tool battery with a nominal voltage of 36 volts.

In contrast to the prior art, by way of the mains-operable battery charging device according to the present invention, a main rechargeable tool battery accommodated in a main charging interface may now be advantageously charged with a main charging voltage and, simultaneously, an auxiliary rechargeable tool battery may be charged with an auxiliary charging voltage which differs from the main charging voltage.

In one preferred embodiment, the main charging interface designed for accommodating the main rechargeable tool battery and the auxiliary charging interface which is connectable to an auxiliary rechargeable tool battery are mechanically encoded differently, the main rechargeable tool battery and the auxiliary rechargeable tool battery being of different types, in particular. In other words, the main charging interface is therefore designed, in particular, only for accommodating the main rechargeable tool battery and, in particular, not for accommodating a different type of auxiliary rechargeable tool battery.

In one particularly preferred embodiment, the auxiliary charging interface is designed as a plug to be plugged into an auxiliary rechargeable tool battery. The present invention incorporates the finding, in this regard, that previously only one main rechargeable tool battery and no auxiliary rechargeable tool batteries of a different type could be charged on battery charging devices from the prior art. In this way, it was previously not possible, for example, to simultaneously charge a main rechargeable tool battery with a nominal voltage of 36 volts and having a first hardware encoding, and an auxiliary rechargeable tool battery with a nominal voltage of 14 volts or 22 volts and having a hardware encoding which differs from the hardware encoding of the main rechargeable tool battery.

Due to the fact that the auxiliary charging interface is preferably designed as a plug to be plugged into an auxiliary rechargeable tool battery, the auxiliary rechargeable tool battery may now be charged simultaneously with a main rechargeable tool battery, even though it is encoded, in particular mechanically, differently. An embodiment of the battery charging device including differently hardware-encoded main charging interfaces is now no longer required. In other words, a mains-operable battery charging device may be designed only for accommodating precisely one mechanically encoded main tool, and a charging of a differently encoded auxiliary rechargeable tool battery may take place with the aid of a corresponding plug.

The battery charging device may include one, two or three or more auxiliary charging interfaces. The battery charging device preferably includes precisely two auxiliary charging interfaces. The battery charging device may include precisely one auxiliary charging interface.

The main charging voltage for charging a main rechargeable tool battery is preferably configured with a nominal voltage of 36 volts. The auxiliary charging voltage is also preferably configured for charging a rechargeable tool battery with a nominal voltage of 14 volts or 22 volts. A first auxiliary charging voltage may be configured for charging a rechargeable tool battery with a nominal voltage of 14 volts. A second auxiliary charging voltage may be configured for charging a rechargeable tool battery with a nominal voltage of 22 volts. Conversely, a first auxiliary charging voltage may be configured for charging a rechargeable tool battery with a nominal voltage of 22 volts. A second auxiliary charging voltage may be configured for charging a tool with a nominal voltage of 14 volts.

In one particularly preferred embodiment, the main charging voltage is configured for charging a main rechargeable tool battery with a nominal voltage of 36 volts, and the main charging interface is designed or mechanically encoded for accommodating a main rechargeable tool battery with 36 volts. Alternatively, the main charging voltage may be designed for charging a main rechargeable tool battery with a nominal voltage of 14 volts or 22 volts, and the main charging interface may be designed for accommodating a main rechargeable tool battery with a nominal voltage of 14 volts or 22 volts.

The auxiliary charging interface may be electrically connected to the same charging electronics system as the main charging interface. Preferably, precisely one charging electronics system is provided both for the main charging interface and for the auxiliary charging interface/the auxiliary charging interfaces.

Preferably, the auxiliary charging interface is connected via an auxiliary charging cable to the battery charging device, in particular to its charging electronics system. A first auxiliary charging interface may be connected via a first auxiliary charging cable to the battery charging device, in particular to its charging electronics system. A second auxiliary charging interface may be connected via a second auxiliary charging cable to the battery charging device, in particular to its charging electronics system.

It has proven advantageous that the battery charging device include a cooling fan situated within the charger housing for cooling the charging electronics system.

The main charging interface may include at least one ventilation channel via which a main rechargeable tool battery accommodated in the main charging interface is coolable with the aid of air drawn in by the cooling fan. The main rechargeable tool battery itself may include a rechargeable battery ventilation channel via which air may flow through the main rechargeable tool battery.

With respect to the charging system, the object is achieved by an above-described, mains-operable battery charging device and a main rechargeable tool battery; the main charging interface of the mains-operable battery charging device is designed for accommodating the main rechargeable tool battery. Preferably, the main charging interface is encoded exclusively mechanically for the main rechargeable tool battery; in particular, the main rechargeable tool battery has a nominal voltage of 36 volts.

Further advantages result from the following description of the figures. The figures illustrate different exemplary embodiments of the present invention. The figures, the description and the claims contain numerous features in combination. Those skilled in the art will advantageously also consider the features individually and combine them to form other meaningful combinations.

### BRIEF DESCRIPTION OF THE DRAWINGS

In the figures, identical and equivalent components are provided with identical reference numerals.

FIG. 1 shows a schematic representation of a first exemplary embodiment of a mains-operable battery charging device according to the present invention;

FIG. 2 shows a schematic representation of a second exemplary embodiment of a mains-operable battery charging device according to the present invention; and

[symbol]

### DETAILED DESCRIPTION

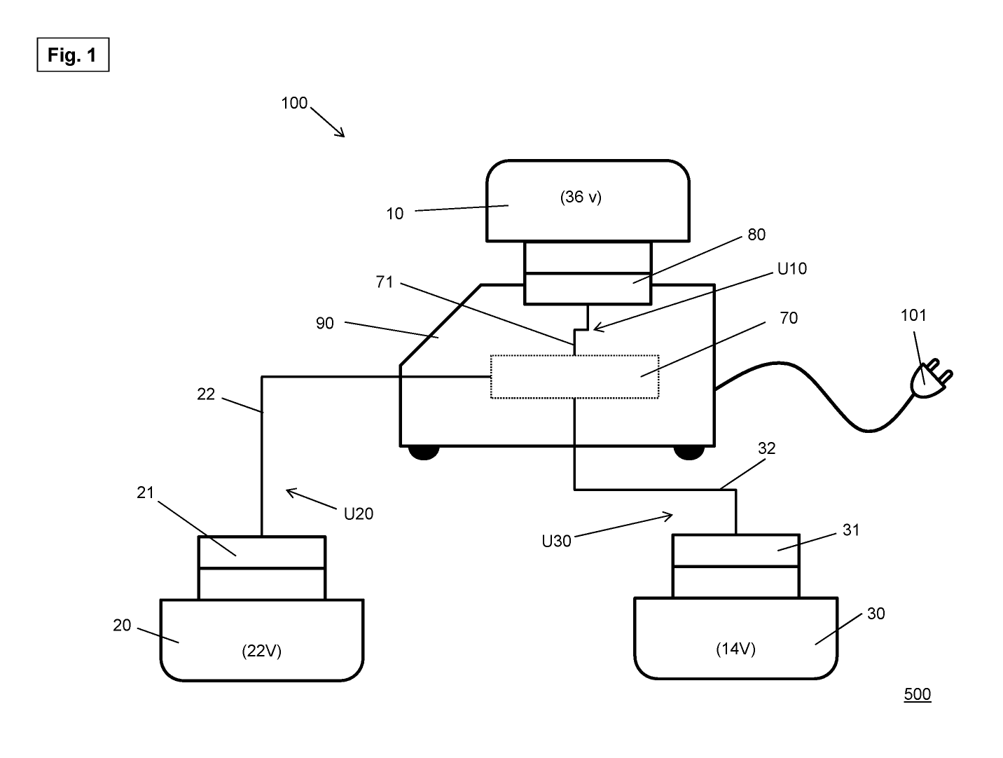

FIG. 1 shows a mains-operable battery charging device 100 including a charger housing 90 which includes a main charging interface 80 designed for exchangeably accommodating a main rechargeable tool battery 10 of a hand-held power tool. Main rechargeable tool battery 10 accommodated in main charging interface 80 in the present case has a nominal voltage of 36 volts. Correspondingly, main charging interface 80 is designed and mechanically encoded for accommodating the main rechargeable tool battery having 36 volts. Mains-operable battery charging device 100 may be connected via a mains plug 101 to a 230-volt AC-voltage network, for example.

Battery charging device 100 includes a charging electronics system 70 which is situated within charger housing 90. Charging electronics system 70 is designed for charging main rechargeable tool battery 10, which is accommodated in main charging interface 80 and has a nominal voltage of 36 volts, with a main charging voltage U10.

Mains-operable battery charging device 100 from FIG. 1 includes a first auxiliary charging interface 21 and a second auxiliary charging interface 31 in the present case. First auxiliary charging interface 21 is connected to charging electronics system 70 via a first auxiliary charging cable 22. Second auxiliary charging interface 31 is connected to charging electronics system 70 via a second auxiliary charging cable 32. First auxiliary rechargeable tool battery 20 shown in FIG. 1 is connected to first auxiliary charging interface 21 in the present case and is chargeable with a first auxiliary charging voltage U20 via the first auxiliary charging interface. Second auxiliary rechargeable tool battery 30, which is connected to battery charging device 100 via second auxiliary charging interface 31, is chargeable with a second auxiliary charging voltage U30 via battery charging device 100. Main charging voltage U10 differs from auxiliary charging voltages U20, U30.

Main charging voltage U10 for charging the main rechargeable tool battery is configured with a nominal voltage of 36 volts in the present case. First auxiliary charging voltage U20 is configured for charging the first auxiliary rechargeable tool battery with a nominal voltage of 22 volts. Second auxiliary charging voltage U30 is configured for charging second auxiliary rechargeable tool battery 30 with a nominal voltage of 14 volts.

As is also apparent from FIG. 1, main charging interface 80 is connected to charging electronics system 70 via an internal charging cable 71. Both first auxiliary charging interface 21 and second auxiliary charging interface 31 are electrically connected to one and the same charging electronics system 70 as main charging interface 80.

Main charging interface 80 of battery charging device 100 is situated directly on charger housing 90, as is apparent. The main rechargeable tool battery, which has a nominal voltage of 36 volts, is chargeable via this main charging interface 80. The main rechargeable tool battery may be plugged into main charging interface 80 for this purpose. First auxiliary charging interface 21 and second auxiliary charging interface 31 are situatable remotely from battery charging device 100 via first auxiliary charging cable 22 and second auxiliary charging cable 32, respectively. In the present case, first auxiliary rechargeable tool battery 20, which has a nominal voltage of 22 volts, is charged remotely by battery charging device 100. Second auxiliary rechargeable tool battery 30, which has a nominal voltage of 14 volts, is also charged remotely by battery charging device 100. Further auxiliary charging interfaces including additional auxiliary charging cables are possible.

Mains-operable battery charging device 100 and main rechargeable tool battery 10, for the accommodation of which main charging interface 80 of mains-operable battery charging device 100 is designed, form a charging system 500 according to the present invention in this case. First auxiliary rechargeable tool battery 20 and/or second auxiliary rechargeable tool battery 30 may be included in charging system 500.

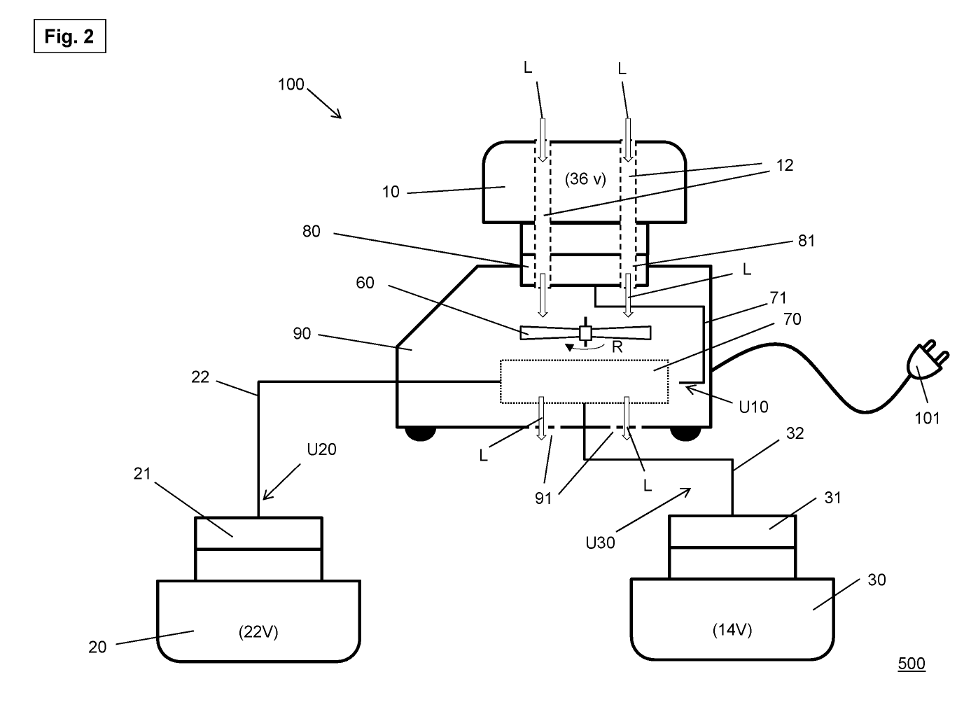

The exemplary embodiment shown in FIG. 2 includes, in addition to the exemplary embodiment described with reference to FIG. 1, a cooling fan 60 situated within charger housing 90, which is situated to cool charging electronics system 70 of battery charging device 100. Main charging interface 80 of battery charging device 100 includes two ventilation channels 81 via which the main rechargeable tool battery accommodated in main charging interface 80 is coolable with the aid of air L drawn in via cooling fan 60. Main rechargeable tool battery 10 includes internal rechargeable battery ventilation channels 12.

During the charging operation, cooling fan 60 of battery charging device 100 rotates in a direction of rotation R. As a result, air L is drawn into main rechargeable tool battery 10 through inner rechargeable battery ventilation channels 12 and, in charger housing 90, is guided further in the direction of charging electronics system 70 and, on its further course, is guided past the charging electronics system, and is finally discharged into the surroundings through outlet openings 91 in the bottom of charger housing 90. Both main rechargeable tool battery 10 to be charged and charging electronics system 70, which is charging main rechargeable tool battery 10 and connected auxiliary rechargeable tool batteries 20 and 30, are cooled with the aid of air L. Cooling fan 60 is operated in such a way that required waste heat may be carried away from main rechargeable tool battery 10 and away from charging electronics system 70 via the air.

With the embodiment of FIG. 1, main charging interface 80 is mechanically encoded only for accommodating main rechargeable tool battery 10. First auxiliary charging interface 21 and second auxiliary charging interface 31 can be mechanically encoded differently from main charging interface 80, since these are designed as plugs to be plugged into an auxiliary rechargeable tool battery.

### LIST OF REFERENCE NUMERALS

U10 main charging voltage
U20 first auxiliary charging voltage
U30 second auxiliary charging voltage
L air
R direction of rotation
10 main rechargeable tool battery
12 rechargeable-battery ventilation channels
20 first auxiliary rechargeable tool battery
21 first auxiliary charging interface
22 first auxiliary charging cable
30 second auxiliary rechargeable tool battery
31 second auxiliary charging interface
32 second auxiliary charging cable
60 cooling fan
70 charging electronics system
71 internal charging cable
80 main charging interface
81 ventilation channel
90 charger housing
91 outlet openings
100 battery charging device
101 mains plug
500 charging system

What is claimed is:

1-10. (canceled)

11: A mains-operable battery charging device comprising:
a charger housing including a main charging interface designed for exchangeably accommodating a main rechargeable tool battery of a hand-held power tool;
a charging electronics system situated within the charger housing and designed for charging a main rechargeable tool battery accommodated in the main charging interface with a main charging voltage;
at least one auxiliary charging interface; and
an auxiliary rechargeable tool battery connectable to the battery charging device via the auxiliary charging interface and chargeable with an auxiliary charging voltage differing from the main charging voltage.

12: The mains-operable battery charging device as recited in claim 11 wherein the main charging interface and the auxiliary charging interface are mechanically encoded differently, the main rechargeable tool battery and the auxiliary rechargeable tool battery being of different types.

13: The mains-operable battery charging device as recited in claim 11 wherein the auxiliary charging interface is designed as a plug to be plugged into the auxiliary rechargeable tool battery.

14: The mains-operable battery charging device as recited in claim 11 wherein the auxiliary charging interface is electrically connected to the charging electronics system.

15: The mains-operable battery charging device as recited in claim 11 wherein the auxiliary charging interface is connected to the battery charging device via an auxiliary charging cable.

16: The mains-operable battery charging device as recited in claim 11 wherein the main charging voltage is configured for charging the main rechargeable tool battery with a nominal voltage of 36 volts.

17: The mains-operable battery charging device as recited in claim 11 wherein the auxiliary charging voltage is configured for charging the rechargeable tool battery with a nominal voltage of 14 volts or 22 volts.

18: The mains-operable battery charging device as recited in claim 11 wherein the battery charging device includes a cooling fan situated within the charger housing for cooling the charging electronics system.

19: The mains-operable battery charging device as recited in claim 18 wherein the main charging interface includes at least one ventilation channel, the main rechargeable tool battery accommodated in the main charging interface is coolable via the ventilation channel with the aid of air drawn in by the cooling fan.

20: A charging system comprising:
the mains-operable battery charging device as recited in claim 11; and
the main rechargeable tool battery, for the accommodation of which the main charging interface of the mains-operable battery charging device is designed.
